(19) United States
(12) Patent Application Publication
(10) Pub. No.: US 2022/0415629 A1
(43) Pub. Date: Dec. 29, 2022

(54) SUBSTRATE SUPPORT, SUBSTRATE SUPPORT ASSEMBLY, AND PLASMA PROCESSING APPARATUS

(71) Applicant: Tokyo Electron Limited, Tokyo (JP)

(72) Inventor: Shingo KOIWA, Kurokawa-gun (JP)

(21) Appl. No.: 17/850,250

(22) Filed: Jun. 27, 2022

(30) Foreign Application Priority Data
Jun. 28, 2021 (JP) 2021-106973

(51) Int. Cl. H01J 37/32

(52) U.S. Cl. CPC H01J 37/32724; H01J 37/3255; H01J 37/32091; H01J 37/32568; H01J 37/32642; H01J 37/32697; H01J 2237/2001

(57) ABSTRACT

A substrate support that supports a substrate, includes a substrate attraction part having an attraction electrode for holding the substrate, an RF electrode part to which RF power is supplied, and a substrate temperature adjuster having a heater electrode for adjusting a temperature of the substrate. The substrate attraction part and the substrate temperature adjuster are stacked with the RF electrode part interposed therebetween.

### CROSS-REFERENCE TO RELATED APPLICATION

This application is based upon and claims the benefit of priority from Japanese Patent Application No. 2021-106973, filed on, Jun. 28, 2021, the entire contents of which are incorporated herein by reference.

### TECHNICAL FIELD

The present disclosure relates to a substrate support, a substrate support assembly, and a plasma processing apparatus.

### BACKGROUND

Patent Document 1 discloses a substrate support having a substrate support body on which a workpiece is placed and in which a heater is provided, and a cooling table in which a refrigerant passage is provided. The substrate support body and the cooling table are separated from each other.

### PRIOR ART DOCUMENTS

### Patent Document

Japanese laid-open publication No. 2017-63011

### SUMMARY

According to one embodiment of the present disclosure, there is provided a substrate support that supports a substrate, includes a substrate attraction part having an attraction electrode for holding the substrate, an RF electrode part to which RF power is supplied, and a substrate temperature adjuster having a heater electrode for adjusting a temperature of the substrate. The substrate attraction part and the substrate temperature adjuster are stacked with the RF electrode part interposed therebetween.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram schematically showing the configuration of a plasma processing system.

FIG. 2 is a longitudinal sectional view showing the outline of the configuration of a plasma processing apparatus.

FIG. 3 is an enlarged explanatory view showing a portion of a substrate support assembly according to an embodiment.

FIG. 4 is an enlarged explanatory view showing a portion of a substrate support assembly according to another embodiment.

FIG. 5 is an enlarged explanatory view showing a portion of a substrate support assembly according to another embodiment.

FIG. 6 is an enlarged explanatory view showing a seal structure according to another embodiment.

FIG. 7 is an enlarged explanatory view showing a portion of the substrate support assembly according to the present embodiment.

FIG. 8 is an enlarged explanatory view showing a portion of a substrate support assembly according to a first example of another embodiment.

FIG. 9 is an enlarged explanatory view showing a seal structure according to the first example of another embodiment.

FIG. 10 is an enlarged explanatory view showing a portion of a substrate support assembly according to a second example of another embodiment.

FIG. 11 is an enlarged explanatory view showing a seal structure according to the second example of another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a semiconductor device, a semiconductor substrate (hereinafter referred to as a “substrate”) is subjected to plasma processing such as etching. In the plasma processing, plasma is generated by exciting a process gas, and a wafer is processed by the plasma.

A plasma processing apparatus that performs a plasma processing generally includes a chamber, a substrate support assembly (stage), and a radio frequency (RF: Radio Frequency) power supply. The RF power supply supplies radio frequency power (RF power) to, for example, an electrode (RF electrode) of the substrate support assembly. In one example, the RF power supply supplies source RF power for generating plasma of the process gas, and bias RF power for drawing ions into the substrate. The substrate support assembly is provided in the chamber. The substrate support assembly has an RF electrode and an electrostatic chuck on the RF electrode.

In recent years, in an etching process, the application of a difficult-to-etch mask material such as BSi, HfO, Ru, or WC has been studied in order to cope with further miniaturization of semiconductor devices. In order to cope with such a difficult-to-etch material, heating the substrate to a high temperature (for example, 200 degrees C. or higher) is an important factor. Further, it has been also suggested that the etching characteristics can be improved, for example, by using the source RF power having a frequency of 13 MHz or more to realize a high electron density (Ne density) and shifting the superimposed bias RF power to a low frequency side such as 400 kHz.

Conventionally, a structure has been proposed for a stage to improve the heat insulating property between a stage body and a base in order to cope with the increase in the temperature of the substrate. However, even if such a stage is applied to a plasma processing apparatus, since the power feeding route of RF power cannot be properly set, a loss of source RF power may occur. It is also difficult to increase the bias RF power.

Therefore, for example, a stage (substrate support) disclosed in Patent Document 1 has been proposed. The stage includes a cooling table, a power feeding body, an electrostatic chuck (substrate support body), a first elastic member, and a fastening member. In this stage, the cooling table and the base are separated from each other by the first elastic member. Further, in this stage, no adhesive is used for bonding between the base and the attraction part. Therefore, it is possible to set the temperature of the electrostatic chuck to a high temperature. Further, since heat exchange between the electrostatic chuck and the cooling table can be performed via a heat transfer gas supplied to a heat transfer space, it is also possible to set the temperature of the electrostatic chuck to a low temperature. Further, in this stage, the power feeding route of RF power to a base of the electrostatic chuck is secured by the power feeding body, the cooling table, and the fastening member. Further, since the power feeding body is not directly connected to the base of the electrostatic chuck but is connected to the cooling table, aluminum or an aluminum alloy can be adopted as a constituent material of the power feeding body. Therefore, even when radio frequency source RF power is used, the loss of source RF power is suppressed. Further, even when low frequency bias RF power is used, a bias RF power having high power is possible.

However, in the above-mentioned stage, since the attraction part of the electrostatic chuck incorporates an electrode and a heater which are for attraction purpose, the thickness of the attraction part made of ceramic is as large as 4mm or more, for example. In such a case, the loss of RF power on the low frequency side becomes large. Further, a potential difference of a space between the substrate and the RF electrode including gas diffusion spaces for a He gas which are scattered in a dielectric layer between the substrate and the RF electrode, becomes large. Then, abnormal discharge is likely to occur on the rear surface of the substrate.

The technique according to the present disclosure suppresses the loss of RF power on the low frequency side with respect to RF power supplied to an RF electrode part in plasma processing.

Hereinafter, a substrate support, a substrate support assembly, and a plasma processing apparatus according to an embodiment will be described with reference to the drawings. Throughout the present disclosure and the drawings, elements having substantially the same functional configuration are denoted by the same reference numerals, so that explanation thereof will not be repeated.

### <Plasma Processing System>

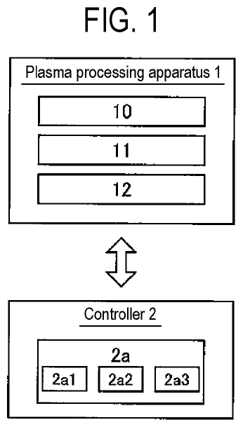

First, a plasma processing system according to one embodiment will be described with reference to FIG. 1. FIG. 1 is an explanatory diagram schematically showing the configuration of a plasma processing system.

In one embodiment, the plasma processing system includes a plasma processing apparatus 1 and a controller 2. The plasma processing apparatus 1 includes a plasma processing chamber 10, a substrate support assembly 11, and a plasma generator 12. The plasma processing chamber 10 has a plasma processing space. Further, the plasma processing chamber 10 has at least one gas supply port for supplying at least one process gas to the plasma processing space, and at least one gas discharge port for discharging a gas from the plasma processing space. The gas supply port is connected to a gas supply 20 to be described later, and the gas discharge port is connected to an exhaust system 30 to be described later. The substrate support assembly 11 is arranged in the plasma processing space and has a substrate support surface for supporting a substrate.

The plasma generator 12 is configured to generate plasma from at least one process gas supplied into the plasma processing space. Plasma formed in the plasma processing space may be capacitively-coupled plasma (CCP), inductively-coupled plasma (ICP), ECR (Electron-Cyclotron-Resonance) plasma, helicon wave plasma (HWP), surface wave plasma (SWP), or the like. Further, various types of plasma generators including an AC (Alternating Current) plasma generator and a DC (Direct Current) plasma generator may be used. In one embodiment, an AC signal (AC power) used in the AC plasma generator has a frequency in a range of 100 kHz to 10 GHz. Therefore, the AC signal includes an RF (Radio Frequency) signal and a microwave signal. In one embodiment, the RF signal has a frequency in a range of 200 kHz to 150 MHz.

The controller 2 processes computer-executable instructions that cause the plasma processing apparatus 1 to perform various steps to be described in the present disclosure. The controller 2 may be configured to control each element of the plasma processing apparatus 1 to perform the various steps to be described herein. In one embodiment, a part or all of the controller 2 may be included in the plasma processing apparatus 1. The controller 2 may include, for example, a computer 2a. The computer 2a may include, for example, a processing part (CPU: Central Processing Unit) 2a1, a storage part 2a2, and a communication interface 2a3. The processing part 2a1 may be configured to perform various control operations based on a program stored in the storage part 2a2. The storage part 2a2 may be a non-transitory computer readable storage medium such as a RAM (Random Access Memory), a ROM (Read Only Memory), a HDD (Hard Disk Drive), a SSD (Solid State Drive), or a combination thereof. The communication interface 2a3 may communicate with the plasma processing apparatus 1 via a communication line such as a LAN (Local Area Network).

### <Plasma Processing Apparatus>

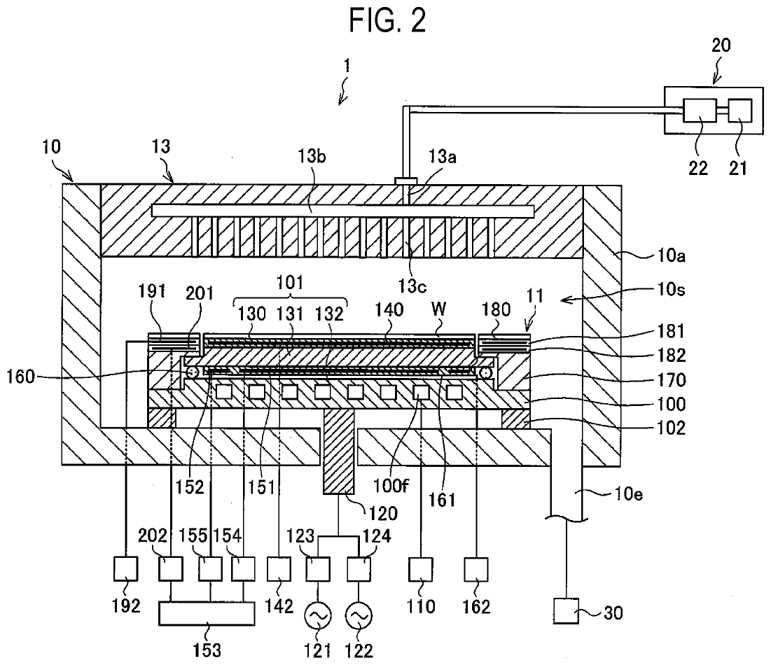

Hereinafter, a configuration example of a capacitively-coupled plasma processing apparatus as an example of the plasma processing apparatus 1 will be described with reference to FIG. 2. FIG. 2 is a longitudinal sectional view showing an outline of the configuration of the plasma processing apparatus 1. In the plasma processing apparatus 1 of the present embodiment, a substrate (wafer) W is subjected to plasma processing, but the substrate W to be plasma-processed is not limited to the wafer.

The capacitively-coupled plasma processing apparatus 1 includes a plasma processing chamber 10, a gas supply 20, and an exhaust system 30. Further, the plasma processing apparatus 1 includes a substrate support assembly 11 and a gas introduction part. The gas introduction part is configured to introduce at least one process gas into the plasma processing chamber 10. The gas introduction part includes a shower head 13. The substrate support assembly 11 is arranged in the plasma processing chamber 10. The shower head 13 is arranged above the substrate support assembly 11. In one embodiment, the shower head 13 constitutes at least a portion of the ceiling of the plasma processing chamber 10. The plasma processing chamber 10 has a plasma processing space 10s defined by the shower head 13, a sidewall 10a of the plasma processing chamber 10, and the substrate support assembly 11. The sidewall 10a is grounded. The shower head 13 and the substrate support assembly 11 are electrically isolated from the housing of the plasma processing chamber 10.

The shower head 13 is configured to introduce at least one process gas from the gas supply 20 into the plasma processing space 10s. The shower head 13 has at least one gas supply port 13a, at least one gas diffusion chamber 13b, and a plurality of gas introduction ports 13c. A process gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. In addition to the shower head 13, the gas introduction part may include one or more side gas injection portions (SGI: Side Gas Injector) attached to one or more openings formed in the sidewall 10a.

The gas supply 20 may include at least one gas source 21 and at least one flow rate controller 22. In one embodiment, the gas supply 20 is configured to supply at least one process gas from the corresponding gas source 21 to the shower head 13 via the corresponding flow rate controller 22. Each flow rate controller 22 may include, for example, a mass flow controller or a pressure-controlled flow rate controller. Further, the gas supply 20 may include at least one flow rate modulation device that modulates or pulses the flow rate of at least one process gas.

The exhaust system 30 may be connected to, for example, a gas discharge port 10e provided at the bottom of the plasma processing chamber 10. The exhaust system 30 may include a pressure regulating valve and a vacuum pump. The pressure regulating valve regulates the internal pressure of the plasma processing space 10s. The vacuum pump may include a turbo molecular pump, a dry pump, or a combination thereof.

### <Substrate Support Assembly>

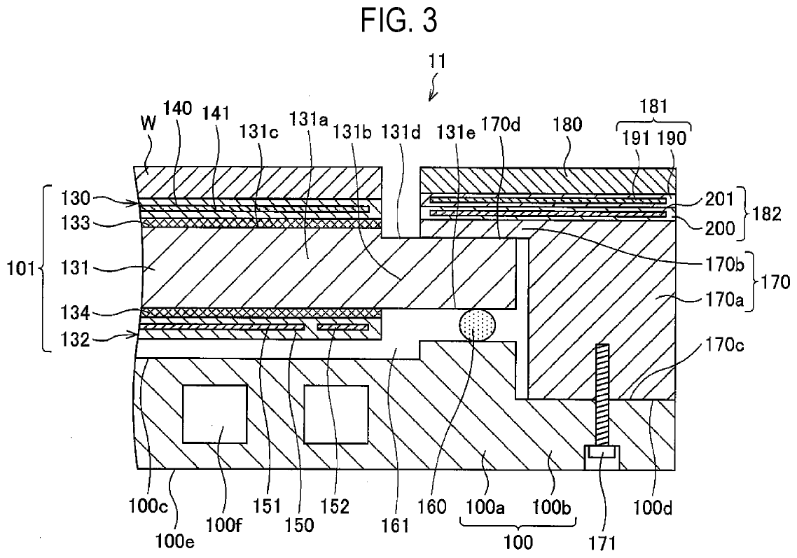

Next, the above-mentioned substrate support assembly 11 and the components of the plasma processing apparatus 1 associated with the substrate support assembly 11 will be described with reference to FIGS. 2 and 3. FIG. 3 is an enlarged explanatory view showing a portion of the substrate support assembly 11.

The substrate support assembly 11 has a base 100 and a substrate support 101. The base 100 is supported by a support member 102 extending from the bottom of the plasma processing chamber 10. The support member 102 is an insulating member and is formed of, for example, aluminum oxide (alumina). Further, the support member 102 has substantially a cylindrical shape.

The base 100 is formed of a conductive metal such as aluminum. The base 100 has substantially a disc shape. The base 100 has a central portion 100a and a peripheral portion 100b. The central portion 100a has substantially a disc shape. The central portion 100a provides a first upper surface 100c of the base 100.

The peripheral portion 100b has substantially an annular shape in a plan view. The peripheral portion 100b is continuous with the central portion 100a and extends in the circumferential direction outside the central portion 100a in the radial direction. The peripheral portion 100b provides a second upper surface 100d of the base 100. The second upper surface 100d is located lower than the first upper surface 100c in the vertical direction. Further, the peripheral portion 100b provides a lower surface 100e of the base 100 together with the central portion 100a.

A flow path 100f for temperature control medium is formed in the base 100. The flow path 100f extends in the base 100, for example, in a spiral shape. A temperature control medium is supplied to the flow path 100f by a chiller unit 110 provided outside the plasma processing chamber 10. The temperature control medium supplied to the flow path 100f is a liquid in the operating temperature range of the plasma processing apparatus 1, for example, in the temperature range of 20 degrees C. or higher and 250 degrees C. or lower. Alternatively, the temperature control medium may be a refrigerant that absorbs heat to perform cooling by its vaporization, or may be, for example, a hydrofluorocarbon-based refrigerant.

A power feeding body 120 is connected to the base 100. The power feeding body 120 is a power feeding rod and is connected to the lower surface 100e of the base 100. The power feeding body 120 is formed of aluminum or an aluminum alloy.

The power feeding body 120 is electrically connected to a first RF power supply 121 and a second RF power supply 122 provided outside the plasma processing chamber 10. The power feeding body 120 transmits RF power from the first RF power supply 121 and the second RF power supply 122, which will be described later.

The first RF power supply 121 is a power supply that generates source RF power for plasma generation. The source RF power, which may have a frequency of 13 MHz to 150 MHz, 40 MHz in one example, is supplied from the first RF power supply 121. The first RF power supply 121 is connected to the power feeding body 120 via a first matching circuit 123. The first matching circuit 123 is a circuit for matching the output impedance of the first RF power supply 121 with the input impedance on the load side. Using the source RF power from the first RF power supply 121, plasma is formed from at least one process gas supplied into the plasma processing space 10s. Therefore, the first RF power supply 121 can function as at least a portion of the plasma generator 12. Further, the first RF power supply 121 may be configured to generate a plurality of source RF powers having different frequencies. Further, the first RF power supply 121 may not be electrically connected to the power feeding body 120, and may be connected to the shower head 13, which is the upper electrode, via the first matching circuit 123.

The second RF power supply 122 is a power supply that generates bias RF power for drawing ions into the substrate W. The bias RF power, which may have a frequency within a range of 400 kHz to 13.56 MHz, 400 kHz in one example, is supplied from the second RF power supply 122. The second RF power supply 122 is connected to the power feeding body 120 via a second matching circuit 124. The second matching circuit 124 is a circuit for matching the output impedance of the second RF power supply 122 and the input impedance on the load side. Further, the second RF power supply 122 may be configured to generate a plurality of bias RF powers having different frequencies. Further, a DC (Direct Current) pulse generator may be used instead of the second RF power supply 122.

The substrate support 101 is disposed on the first upper surface 100c side of the base 100. The substrate support 101 has a substrate attraction part 130, an RF electrode part 131, and a substrate temperature adjuster 132. The substrate attraction part 130, the RF electrode part 131, and the substrate temperature adjuster 132 are stacked in this order from the upper side to the lower side. That is, the substrate attraction part 130 and the substrate temperature adjuster 132 are stacked with the RF electrode part 131 interposed therebetween.

A bonding layer 133 that bonds the substrate attraction part 130 and the RF electrode part 131 is disposed between the substrate attraction part 130 and the RF electrode part 131. Similarly, a bonding layer 134 that bonds the RF electrode part 131 and the substrate temperature adjuster 132 is disposed between the RF electrode part 131 and the substrate temperature adjuster 132. A method of bonding by the bonding layers 133 and 134 is not particularly limited, but may be, for example, metal bonding using metal, or may be adhesive bonding using an adhesive.

The substrate attraction part 130 has a configuration in which an attraction electrode 141 is provided inside a first base layer 140. The first base layer 140 has, for example, substantially a disc shape having a thickness of 2 mm or less. The first base layer 140 is made of a dielectric, for example, ceramics. The ceramics used for the first base layer 140 can be selected based on an electrostatic force when the substrate W is attracted and held.

For example, when a Coulomb force is generated to hold the substrate W, ceramics having the volume resistivity of 1×10¹⁵ Ω·cm or more in a temperature range of room temperature (for example, 20 degrees C.) or higher and 400 degrees C. or lower is used for the first base layer 140. As such ceramics, for example, aluminum oxide (alumina), which is a metal oxide, can be used.

Further, for example, when a Johnson-Rahbeck force is generated to hold the substrate W, ceramics having the volume resistivity of 1×10⁻⁸ to 1×10⁻¹¹ Ω·cm in a temperature range of room temperature (for example, 20 degrees C.) or higher and 400 degrees C. or lower is used for the first base layer 140. As such ceramics, for example, aluminum nitride (ALN), which is a metal nitride, can be used. In any case, when the first base layer 140 made of ceramics is used, a sufficient attraction force is exhibited even at a high temperature exceeding 200 degrees C. Further, a dielectric other than ceramics, for example, polyimide, may be used for the first base layer 140.

The attraction electrode 141 is an electrode film having conductivity. A direct current (DC) power supply 142 is electrically connected to the attraction electrode 141. When a DC voltage from the DC power supply 142 is applied to the attraction electrode 141, the substrate attraction part 130 generates the electrostatic force of the above-mentioned Coulomb force or Johnson-Rahbeck force to hold the substrate W by the electrostatic force.

The RF electrode part 131 is made of a conductor. The RF electrode part 131 may be formed of metal such as molybdenum, or may be formed of ceramics obtained by imparting conductivity to, for example, aluminum nitride or silicon carbide. The material of the RF electrode part 131 is selected in combination with the first base layer 140 of the substrate attraction part 130. For example, the material of the RF electrode part 131 is preferably a material having a difference of 1 ppm/degrees C. or less in coefficient of thermal expansion between the RF electrode part 131 and the first base layer 140. Similarly, the material of the RF electrode part 131 is selected in combination with a second base layer 150 of the substrate temperature adjuster 132, which will be described later. For example, the material of the RF electrode part 131 is preferably a material having a difference of 1 ppm/degrees C. or less in coefficient of thermal expansion between the RF electrode part 131 and the second base layer 150. In such a case, an expansion difference between the RF electrode part 131 and the first base layer 140 can be suppressed, and an expansion difference between the RF electrode part 131 and the second base layer 150 can be suppressed, so that the amount of particles generated due to scratches or the like can be reduced.

The RF electrode part 131 has substantially a disc shape. The RF electrode part 131 has a central portion 131a and a peripheral portion 131b. The diameter of the central portion 131a is substantially the same as the diameter of the first base layer 140 of the substrate attraction part 130, and the peripheral portion 131b protrudes outward in the radial direction from the substrate attraction part 130. The central portion 131a has substantially a disc shape. The central portion 131a provides a first upper surface 131c of the RF electrode part 131.

The peripheral portion 131b has substantially an annular shape in a plan view. The peripheral portion 131b is continuous with the central portion 131a and extends in the circumferential direction outside the central portion 131a in the radial direction. The peripheral portion 131b provides a second upper surface 131d of the RF electrode part 131. The second upper surface 131d is located lower than the first upper surface 131c in the vertical direction. Aluminum oxide (alumina) may be sprayed on the second upper surface 131d. Further, the peripheral portion 131b provides a lower surface 131e of the RF electrode part 131 together with the central portion 131a.

The substrate temperature adjuster 132 has a configuration in which heater electrodes 151 and 152 are provided inside the second base layer 150. The second base layer 150 has substantially a disc shape. The diameter of the second base layer 150 is substantially the same as the diameter of the first base layer 140 of the substrate attraction part 130. The second base layer 150 is formed of the same material as the first base layer 140.

The heater electrode 151 is disposed on the central side of the substrate temperature adjuster 132 with respect to the heater electrode 152. The heater electrode 151 and the heater electrode 152 are each electrically connected to a heater power supply 153. The heater power supply 153 is a three-line heater power supply. A filter 154 may be disposed between the heater electrode 151 and the heater power supply 153 in order to prevent RF noise from entering the heater power supply 153. Further, a filter 155 may be disposed between the heater electrode 152 and the heater power supply 153 in order to prevent RF noise from entering the heater power supply 153. When a voltage from the heater power supply 153 is applied to the heater electrodes 151 and 152, the substrate W is adjusted to a desired temperature.

An elastic member 160 as a first elastic member is disposed between the RF electrode part 131 (the substrate support 101) and the base 100. The elastic member 160 is in contact with the first upper surface 100c of the base 100 and the lower surface 131e of the RF electrode part 131. The elastic member 160 separates the substrate support 101 upward from the base 100. The elastic member 160 is an O-ring. The elastic member 160 is configured to have a thermal resistance higher than the thermal resistance of a heat transfer space 161 when a He gas is supplied to the heat transfer space 161. Further, the elastic member 160 is required to have a low thermal conductivity and a high heat resistance. Such an elastic member 160 may be formed from, for example, a perfluoroelastomer.

A space surrounded by the base 100, the substrate support 101, and the elastic member 160 is formed as the heat transfer space 161 to which a heat transfer gas is supplied. The heat transfer space 161 is sealed by the elastic member 160 between the base 100 and the substrate support 101. The heat transfer space 161 is configured to supply the heat transfer gas, for example, a He gas, from a gas supply 162 provided outside the plasma processing chamber 10.

The substrate support assembly 11 further has a fastening member 170. The fastening member 170 is configured to sandwich the elastic member 160 between the base 100 and the RF electrode part 131. The fastening member 170 is formed of a material having a low thermal conductivity, for example, titanium, in order to suppress heat conduction from the fastening member 170 between the RF electrode part 131 and the base 100.

The fastening member 170 has a tubular portion 170a and an annular portion 170b. The tubular portion 170a has substantially a cylindrical shape and provides a first lower surface 170c at the lower end thereof. The annular portion 170b has substantially an annular plate shape, is continuous with the inner edge of the upper portion of the tubular portion 170a, and extends in the radial direction inward from the tubular portion 170a. The annular portion 170b provides a second lower surface 170d.

The fastening member 170 is arranged so that the first lower surface 170c is in contact with the second upper surface 100d of the base 100 and the second lower surface 170d is in contact with the second upper surface 131d of the RF electrode part 131. Further, the fastening member 170 is fixed to the peripheral portion 100b of the base 100 by a screw 171. By adjusting the screwing of the screw 171 with respect to the fastening member 170, the crushing amount of the elastic member 160 is adjusted.

Further, an elastic member (not shown) may be disposed between the second lower surface 170d of the fastening member 170 and the second upper surface 131d of the RF electrode part 131. This elastic member is an O-ring and prevents particles (for example, metal powder), which may be generated by friction between the second lower surface 170d and the second upper surface 131d, from moving to the substrate attraction part 130 side.

An edge ring 180, an edge ring attraction part 181, and an edge ring temperature adjuster 182 are disposed on the upper surface side of the fastening member 170. The edge ring 180, the edge ring attraction part 181, and the edge ring temperature adjuster 182 are stacked in this order from the upper side to the lower side. The edge ring 180 is arranged so as to surround the substrate W placed on the substrate support 101 (the substrate attraction part 130). The edge ring 180 improves the uniformity of plasma processing on the substrate W.

The edge ring attraction part 181 has the same configuration as the substrate attraction part 130. That is, the edge ring attraction part 181 has a configuration in which an attraction electrode 191 as a second attraction electrode is provided inside a third base layer 190. The third base layer 190 has, for example, a thickness of 2 mm or less and has substantially an annular shape in a plan view. The third base layer 190 is formed of the same material as the first base layer 140 and can be selected based on an electrostatic force (Coulomb force or Johnson-Rahbeck force) when attracting and holding the edge ring 180.

The attraction electrode 191 is an electrode film having conductivity. A DC power supply 192 is electrically connected to the attraction electrode 191. When a DC voltage from the DC power supply 192 is applied to the attraction electrode 191, the edge ring attraction part 181 generates an electrostatic force of Coulomb force or Johnson-Rahbeck force to hold the edge ring 180 by the electrostatic force.

The edge ring temperature adjuster 182 has a configuration in which a heater electrode 201 as a second heater electrode is provided inside a fourth base layer 200. The fourth base layer 200 has substantially an annular shape in a plan view. The fourth base layer 200 may be formed of the same material as the third base layer 190.

The heater electrode 201 is electrically connected to the heater power supply 153. The filter 154 may be disposed between the heater electrode 201 and the heater power supply 153 in order to prevent RF noise from entering the heater power supply 153. When a voltage from the heater power supply 153 is applied to the heater electrode 201, the edge ring 180 is adjusted to a desired temperature.

Further, the substrate support assembly 11 has a gas line (not shown) for supplying a heat transfer gas (for example, a He gas) between the substrate W and the substrate attraction part 130. A gas diffusion space (not shown) in which this heat transfer gas diffuses is formed between the substrate W and the substrate attraction part 130.

### <Plasma Processing Method>

Next, plasma processing performed by using the plasma processing system configured as described above will be described. As the plasma processing, for example, an etching process or a film-forming process is performed.

First, the substrate W is loaded into the plasma processing chamber 10, and the substrate W is placed on the substrate support 101. After that, by applying a DC voltage to the attraction electrode 141 of the substrate attraction part 130, the substrate W is electrostatically attracted and held on the substrate attraction part 130 by a Coulomb force or Johnson Rahbeck force. Further, after the substrate W is loaded, the interior of the plasma processing chamber 10 is depressurized to a desired degree of vacuum by the exhaust system 30.

Next, a process gas is supplied from the gas supply 20 into the plasma processing space 10s via the shower head 13. Further, the source RF power for plasma generation is supplied to the RF electrode part 131 by the first RF power supply 121. The source RF power from the first RF power supply 121 is supplied to the RF electrode part 131 via the power feeding body 120, the base 100, and the fastening member 170. That is, in the substrate support 101, a power feeding route for the source RF power is secured. Then, the process gas is excited to generate plasma. At this time, the bias RF power for drawing ions may be supplied by the second RF power supply 122. Then, plasma processing is carried out to the substrate W by the action of the generated plasma.

According to the above embodiment, in the substrate support assembly 11, the base 100 and the RF electrode part 131 are separated from each other by the elastic member 160. Therefore, it is possible to set the temperature of the substrate temperature adjuster 132 to a high temperature exceeding, for example, 200 degrees C. Further, since heat exchange between the substrate support 101 and the base 100 can be performed via the heat transfer gas supplied into the heat transfer space 161, it is also possible to set the temperature of the substrate temperature adjuster 132 to a low temperature (for example, 80 degrees C.).

Further, according to the present embodiment, in the substrate support assembly 11, a power feeding route of RF power to the RF electrode part 131 is secured by the power feeding body 120, the base 100, and the fastening member 170. Further, since the power feeding body 120 is not directly connected to the RF electrode part 131 but is connected to the base 100, aluminum or an aluminum alloy can be adopted as the constituent material of the power feeding body 120. Therefore, even when radio frequency source RF power is used, the loss of source RF power is suppressed. Further, even when low frequency bias RF power is used, it is possible to implement the bias RF power having high power.

Further, according to the present embodiment, the substrate support 101 has a structure in which the substrate attraction part 130 including the attraction electrode 141 is vertically separated from the substrate temperature adjuster 132 including the heater electrodes 151 and 152 and the RF electrode part 131 is sandwiched between the substrate attraction part 130 and the substrate temperature adjuster 132. By separating the attraction electrode 141 from the heater electrodes 151 and 152 in this way, the thickness of the substrate attraction part 130 can be reduced, and as a result, the loss of RF power on the low frequency side such as 400 kHz can be suppressed. Further, a potential difference between the substrate W and the RF electrode part 131 (including the gas diffusion space of the heat transfer gas existing between the substrate and the substrate attraction part 130) can be reduced, so that abnormal discharge on the rear surface of the substrate W can be suppressed.

In particular, in the present embodiment, since the thickness of the substrate attraction part 130 (the first base layer 140) is as thin as 2 mm or less, the substrate attraction part 130 can be made into a high dielectric. As a result, the loss of RF power on the low frequency side described above can be further suppressed, and the potential difference between the substrate W and the RF electrode part 131 can be further suppressed. As a result of an experiment actually conducted by the inventors, when the thickness of the substrate attraction part 130 was set to 2 mm or less, the loss of RF power (voltage) could be suppressed to 20% or less. Further, when the thickness of the substrate attraction part 130 was set to 2 mm or less, the potential difference between the substrate W and the RF electrode part 131 could be suppressed to 2 kV or less. This potential difference of 2 kV or less is a potential difference that can suppress abnormal discharge on the rear surface of the substrate W.

Further, according to the present embodiment, since the RF electrode part 131 having conductivity is sandwiched between the substrate attraction part 130 and the substrate temperature adjuster 132, the RF electrode part 131 functions as a heat diffusion layer. In such a case, the temperature uniformity of the upper surface of the substrate attraction part 130 can be improved, and as a result, in-plane uniformity of the plasma processing on the substrate W can be improved.

Further, according to the present embodiment, the material of the first base layer 140 of the substrate attraction part 130 is the same as the material of the second base layer 150 of the substrate temperature adjuster 132. In such a case, when the substrate attraction part 130, the RF electrode part 131, and the substrate temperature adjuster 132 are stacked and bonded, the warp of the substrate support 101 can be suppressed.

Further, according to the present embodiment, the material of the RF electrode part 131 is a material in which a difference in coefficient of thermal expansion between the RF electrode part 131 and the first base layer 140 of the substrate attraction part 130 is 1 ppm/degrees C. or less and a difference in coefficient of thermal expansion between the RF electrode part 131 and the second base layer 150 of the substrate temperature adjuster 132 is 1 ppm/degrees C. or less. In such a case, since the expansion difference between the RF electrode part 131 and the first base layer 140 can be suppressed and the expansion difference between the RF electrode part 131 and the second base layer 150 can be suppressed, the amount of particles generated due to scratches or the like can be reduced.

Further, according to the present embodiment, by appropriately selecting the material of the first base layer 140 of the substrate attraction part 130, Coulomb force and Johnson-Rahbeck force can be selectively applied as the electrostatic force when attracting the substrate W. For example, when ceramics having the volume resistivity of 1×10¹⁵ Ω·cm or more is used, Coulomb force can be generated. Further, for example, when ceramics having the volume resistivity of 1×10⁻⁸ to 1×10⁻¹¹ Ω·cm is used, Johnson-Rahbeck force can be generated.

In the attraction method of the substrate W by Coulomb force (hereinafter referred to as “Coulomb attraction”), it may be difficult to attract the substrate W in a high temperature region of 250 degrees C. or higher. On the other hand, in the attraction method of the substrate W by the Johnson-Rahbeck force (hereinafter referred to as “JR attraction”), the substrate W can be attracted even in such a high temperature region.

In the Coulomb attraction, a distance between a contact surface between the substrate W and the substrate attraction part 130 and the attraction electrode 141 mainly affects an attraction force. Therefore, if the upper surface of the substrate attraction part 130 is subjected to, for example, cleaning in a state where the substrate W is not placed on the substrate attraction part 130 (WLDC: Wafer-Less Dry Cleaning), the thickness of the first base layer 140 becomes smaller. As a result, the distance may be reduced and the attraction force to the substrate W may change. On the other hand, in the JR attraction, a large voltage is applied to a minute gap (gas diffusion space) between the substrate W and the substrate attraction part 130, and the attraction force to the substrate W does not depend on the above distance. Therefore, for example, by making a surface layer after WLDC constant, the attraction force of the substrate W can be stabilized even if the thickness of the first base layer 140 becomes smaller.

Further, due to the RF heat input during the plasma processing, the substrate W and the substrate attraction part 130 repeat thermal expansion and contraction. In this respect, in the case of the JR attraction, for example, aluminum nitride (ALN) is used for the first base layer 140, so that the coefficient of thermal expansion of the substrate W is 4 ppm/degrees C., which is substantially the same as that of the first base layer 140, thereby repeating the thermal expansion and contraction with substantially the same behavior. As a result, it is possible to reduce the amount of particles generated due to scratches and the like.

Further, according to the present embodiment, the substrate temperature adjuster 132 has a configuration in which the heater electrodes 151 and 152 are provided inside the second base layer 150. In such a case, the heater electrodes 151 and 152 are difficult to be oxidized and the resistance of the heater electrodes 151 and 152 can be stabilized, so that the temperature of the substrate W can be appropriately adjusted. Further, in the substrate temperature adjuster 132, it is also possible to provide the heater electrodes 151 and 152 on the surface of the second base layer 150. In this case, the heater electrodes 151 and 152 can be formed on the surface of the second base layer 150 by thermal spraying or deposition, and the heater electrodes 151 and 152 are bonded to the RF electrode part 131.

Further, according to the present embodiment, the edge ring attraction part 181 and the edge ring temperature adjuster 182 are vertically separated and stacked. Therefore, the same effects as those of the substrate support 101 can be enjoyed.

### <Other Embodiments>

In the above embodiment, the substrate support 101 may be partitioned into a plurality of regions, and the heater electrode 151 may be provided in each of the plurality of regions in the substrate temperature adjuster 132. In such a case, since the temperature of the substrate W can be adjusted for each of the plurality of regions, in-plane uniformity of the temperature of the substrate W can be improved.

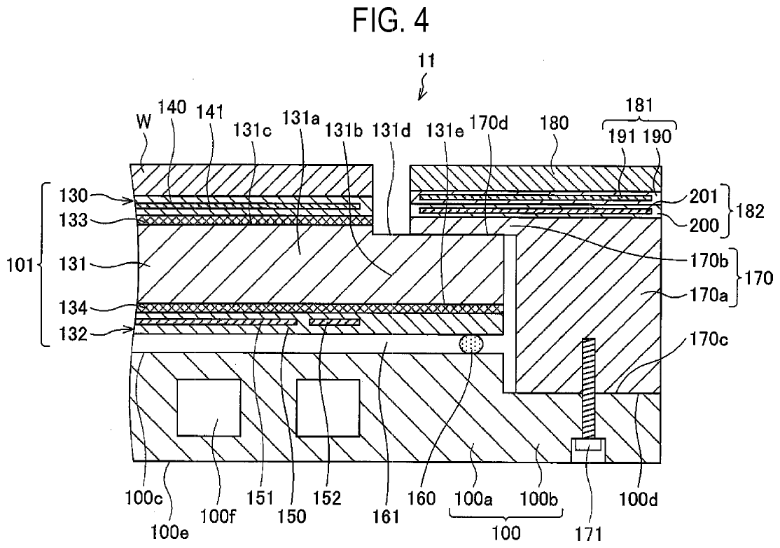

Further, in the above embodiment, the diameter of the substrate temperature adjuster 132 is substantially the same as the diameter of the substrate attraction part 130, i.e., the diameter of the substrate temperature adjuster 132 is smaller than the diameter of the RF electrode part 131, but the size of the substrate temperature adjuster 132 is not limited thereto. For example, as shown in FIG. 4, the diameter of the substrate temperature adjuster 132 may be substantially the same as the diameter of the RF electrode part 131. In this case, the elastic member 160 is arranged between the first upper surface 100c of the base 100 and the lower surface of the second base layer 150 of the substrate temperature adjuster 132. Further, in FIG. 4, the heater electrode 152 of the substrate temperature adjuster 132 is arranged at a position corresponding to the outer peripheral portion of the attraction electrode 141, but the heater electrode 152 may be arranged to extend to the outer edge of the substrate temperature adjuster 132. In this case, since the temperatures on the central side and the outer peripheral side of the RF electrode 131 can be controlled to the same extent, in-plane uniformity of the substrate W can be improved.

Further, in the above embodiment, the substrate attraction part 130, the RF electrode part 131, and the substrate temperature adjuster 132 are stacked in this order from the upper side to the lower side, but the substrate temperature adjuster 132 may be arranged on the upper surface side of the RF electrode part 131, and the substrate attraction part 130 may be arranged on the lower surface side of the RF electrode part 131. However, from the viewpoint of more appropriately attracting the substrate W, it is preferable to arrange the substrate attraction part 130 at a position close to the substrate W, and it is preferable to arrange the substrate attraction part 130 on the upper surface side of the RF electrode part 131 as in the above embodiment.

Further, in the above embodiment, the space surrounded by the base 100, the substrate support 101, and the elastic member 160 is formed as the heat transfer space 161 to which the heat transfer gas is supplied, but the heat transfer space 161 may be omitted.

Further, in the above embodiment, the edge ring 180 is attracted and held by the edge ring attraction part 181, but a method of holding the edge ring 180 is not limited thereto. For example, the edge ring 180 may be attracted and held using an attraction sheet, or the edge ring 180 may be held by clamping. Alternatively, the edge ring 180 may be held by the weight of the edge ring 180. In such a case, the edge ring attraction part 181 is omitted.

### <Other Embodiments>

As described above, in the etching process, the application of a difficult-to-etch mask material has been studied. In order to cope with such a difficult-to-etch mask material, it is required to raise the temperature of the substrate W, and the temperature of the substrate temperature adjuster 132 may be set to a temperature, for example, 300 degrees C. or higher, which is higher than that in the above embodiment. In such a case, since the elastic member 160 also needs to have further heat resistance, there is a possibility that a normal O-ring cannot be applied. Therefore, it is conceivable to use metal (metal seal) as the elastic member 160 that can withstand 300 degrees C. or higher.

However, when metal is used for the elastic member 160, since the metal is hard, it is considered that a large fastening force may be required in order to exhibit sufficient sealing performance. For example, in comparison with a case of using a rubber seal (O-ring) that is commonly used in the general plasma processing apparatus, a fastening force several to several tens of times higher is required, and accordingly, the number of fastening members 170 (bolts) will also increase significantly.

Further, when metal is used for the elastic member 160, the metal has plasticity, so that it cannot be reused, which may make it difficult to deal with parts such as the substrate support 101 which can be subjected to disassembling. As described above, a portion to which the elastic member 160 is applied is required to have a structure capable of ensuring the sealing property even at 300 degrees C. or higher and capable of simple operations as the O-ring does.

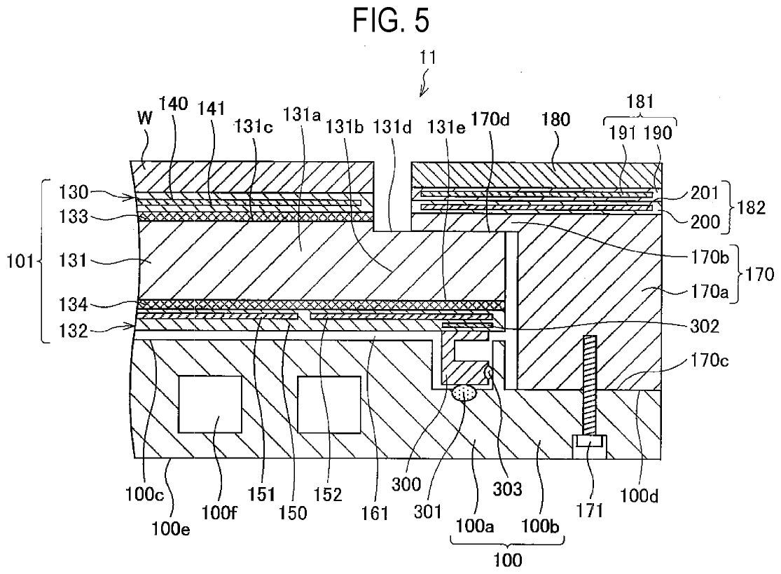

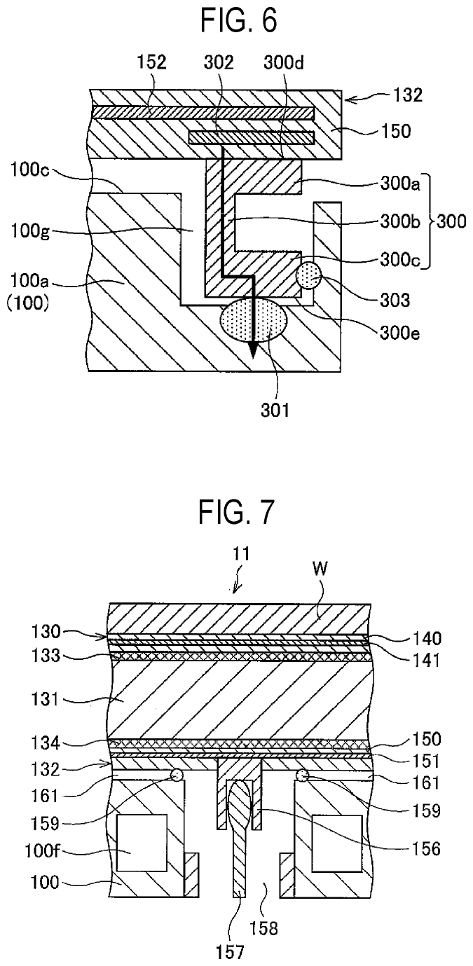

FIG. 5 is an enlarged explanatory view showing a portion of the substrate support assembly 11 according to another embodiment. FIG. 6 is an enlarged explanatory view showing a seal structure according to another embodiment. In this embodiment, the thermal resistances of the substrate temperature adjuster 132 and the base 100 are set to be increased by the He gas in the heat transfer space 161 so that, for example, the temperature of the base 100 is 60 degrees C. or lower even if the temperature of the substrate temperature adjuster 132 is 300 degrees C. or higher.

In this embodiment, instead of the elastic member 160 of the above embodiment, a heat insulating member 300 and a first elastic member 301 are disposed between the substrate temperature adjuster 132 (the substrate support 101) and the base 100. The heat insulating member 300 is disposed on the substrate temperature adjuster 132 side, and the first elastic member 301 is disposed on the base 100 side. The heat insulating member 300 and the first elastic member 301 are arranged in a groove portion 100g formed on the first upper surface 100c of the central portion 100a of the base 100.

The heat insulating member 300 is made of a conductor. Further, it is desirable that the heat insulating member 300 has a low thermal conductivity. For example, metal having a low thermal conductivity such as titanium may be used for the heat insulating member 300. Alternatively, the heat insulating member 300 may employ a shape having low heat transfer property, for example, a stainless flexible tube or the like.

The heat insulating member 300 has an upper annular portion 300a, a cylindrical portion 300b, and a lower annular portion 300c. The upper annular portion 300a has substantially an annular plate shape and provides an upper surface 300d at the upper end thereof. The upper surface 300d is in close contact with the lower surface of the second base layer 150 of the substrate temperature adjuster 132. A seal band may be attached to the upper surface 300d in order to ensure airtightness (sealability). Further, in order to suppress heat transfer between the upper surface 300d and the substrate temperature adjuster 132 by reducing the contact area between the upper surface 300d and the substrate temperature adjuster 132, dots may be formed on the second upper surface 100d. The cylindrical portion 300b has substantially a cylindrical shape and extends vertically and continuously downward from a portion of the upper annular portion 300a on the innermost side of the lower surface of the upper annular portion 300a. The cylindrical portion 300b may be smaller than the sectional area of the upper annular portion 300a, that is, smaller than the thickness of the upper annular portion 300a. The lower annular portion 300c has substantially an annular plate shape and continuously extends from the lower end of the cylindrical portion 300b to extend radially outward from the cylindrical portion 300b. Further, the lower annular portion 300c provides a lower surface 300e at the lower end thereof. A gap is formed between the lower surface 300e and the base 100.

In such a heat insulating member 300, since the area of the upper surface 300d of the upper annular portion 300a is large, the sealing property can be ensured. Further, by providing the cylindrical portion 300b, a heat transfer distance from the substrate temperature adjuster 132 to the first elastic member 301 can be lengthened, as will be described later, so that the temperature of the first elastic member 301 can be lowered. Moreover, due to the shape of the heat insulating member 300, sufficient sealing property and heat insulating property can be exhibited even in a reduced space. The shape of the heat insulating member 300 is not limited to this embodiment. As long as the heat insulating member 300 has a function required for the heat insulating member 300, that is, a function having both the sealing property and the heat insulating property, for example, it may have a cylindrical shape having a small thickness (thin-walled). Alternatively, the sectional shape of the heat insulating member 300 may be, for example, a T-shape or an I-shape. Regardless of the shape, when the sectional area of the cylindrical portion 300b is smaller than the sectional area of the upper annular portion 300a, the stable sealing property can be ensured.

The first elastic member 301 is provided in the groove portion 100g of the base 100 and is in contact with the lower surface 300e of the lower annular portion 300c. The first elastic member 301 is, for example, an O-ring and seals the heat transfer space 161. Further, the first elastic member 301 separates the heat insulating member 300 upward from the base 100. Further, the first elastic member 301 may be buried in the base 100, or may be buried in the heat insulating member 300.

An attraction electrode 302 as a third attraction electrode for holding the heat insulating member 300 is provided inside the second base layer 150 of the substrate temperature adjuster 132. The attraction electrode 302 is an electrode film having conductivity. A DC power supply (not shown) is electrically connected to the attraction electrode 302. When a DC voltage from the DC power supply is applied to the attraction electrode 302, an electrostatic force of Coulomb force or Johnson Rahbeck force is generated, and the heat insulating member 300 is held by the electrostatic force. Further, by this electrostatic force, the sealing properties of the upper surface 300d of the upper annular portion 300a and the lower surface of the second base layer 150 are ensured to appropriately seal the heat transfer space 161. Further, the DC power supply may be provided separately from the DC power supply 142, or may be provided in common.

As described above, in the seal structure of the present embodiment, the sealing property of the upper surface 300d side of the heat insulating member 300 is ensured by the electrostatic force (and the dots and the seal band formed on the upper surface 300d), and the sealing property of the lower surface 300e side of the heat insulating member 300 is ensured by the first elastic member 301.

In such a seal structure, heat is transferred as indicated by an arrow in FIG. 6, and the heat from the substrate temperature adjuster 132 is transferred to the first elastic member 301 via the heat insulating member 300. Here, as described above, the thermal conductivity of the heat insulating member 300 is low. In addition, since the heat insulating member 300 has a shape including the upper annular portion 300a, the cylindrical portion 300b, and the lower annular portion 300c, the heat transfer distance from the substrate temperature adjuster 132 to the first elastic member 301 can be lengthened. Then, the temperature rise of the first elastic member 301 can be suppressed. For example, even when the temperature of the substrate temperature adjuster 132 is 300 degrees C. or higher, for example, 350 degrees C., the temperature can be suppressed to a temperature at which the first elastic member 301 is not damaged, for example, 200 degrees C. or lower. As a result, the sealing property by the first elastic member 301 can be stably exhibited.

Further, since the O-ring can be used for the first elastic member 301, in comparison with the metal seal, the fastening force can be reduced, so that the number of fastening members 170 can be decreased. Further, the first elastic member 301 can be reused and can be operated more easily than the metal seal.

A contact member 303 may be disposed between the outer side surface of the lower annular portion 300c of the heat insulating member 300 and the inner side surface of the groove portion 100g of the base 100. The contact member 303 is provided in an annular shape along the outer side surface of the lower annular portion 300c. The contact member 303 electrically conducts the heat insulating member 300 and the base 100. The contact member 303 is a conductor having high resistance, and for example, a spiral seal, a Bal seal, or the like is used for the contact member 303. By providing the contact member 303, the electrostatic force generated by the attraction electrode 302, that is, the attraction force of the heat insulating member 300, can be stabilized.

When a voltage is applied to the attraction electrode 302, the attraction electrode 302 functions as a capacitor to accumulate charges. Here, if the contact member 303 is not provided, a gap between the lower annular portion 300c of the heat insulating member 300 and the base 100 also functions as a capacitor to accumulate charges, so that the applied voltage is distributed to the capacitor of the attraction electrode 302 and the capacitor of the gap. Therefore, only a portion of the applied voltage is used for the attraction electrode 302, and an attraction voltage drops. Moreover, since the above-mentioned gap has some variation depending on the assembly accuracy and the tolerance between parts, the voltage distribution rate varies, and the attraction voltage is not stable.

To the contrary, when the contact member 303 is provided as in the present embodiment, no capacitor is formed in the gap, and only the attraction electrode 302 functions as a capacitor. Then, the applied voltage is efficiently used for the attraction electrode 302, the attraction voltage is stabilized, and it is possible to suppress the loss of the attraction voltage.

Further, an installation position of the contact member 303 is not limited to the present embodiment. The contact member 303 may be disposed on the lower surface 300e, for example, as long as the heat insulating member 300 and the base 100 can be electrically connected.

Further, for example, when the first elastic member 301 has the conductivity, the first elastic member 301 functions in the same manner as the contact member 303. In such a case, the contact member 303 may be omitted.

In the present embodiment, the heat insulating member 300 is held by the electrostatic force of the attraction electrode 302, but a method of holding the heat insulating member 300 is not limited thereto. For example, the upper surface 300d of the heat insulating member 300 may be held on the lower surface of the second base layer 150 by known means such as adhesion, brazing, and diffusion bonding. In such a case, the contact member 303 may be omitted.

Further, the seal structure of the present embodiment can also be applied to the substrate support assembly 11 in which both the attraction electrode 141 and the heater electrodes 151 and 152 are provided in one base layer.

### <Other Embodiments>

In this embodiment, as shown in FIG. 7, the heater electrode 151 (the heater electrode 152) is electrically connected to a power feeding line 157 via a heater terminal 156, and the power feeding line 157 is connected to the heater power supply 153. The heater terminal 156 is made of heat resistant metal such as molybdenum or tungsten. A portion of the power feeding line 157 connected to the heater terminal 156 constitutes a jack pin which can be inserted into and removed from the heater terminal 156. Further, elastic members 159 are disposed between a power feeding space 158 in which the heater terminal 156 and the power feeding line 157 are provided and the heat transfer space 161. The elastic member 159 is disposed between the substrate temperature adjuster 132 and the base 100. The power feeding space 158 is formed for each of the heater electrodes 151 and 152.

Here, as described above, in order to cope with the difficult-to-etch mask material, the substrate W is required to have a high temperature, and the temperature of the substrate temperature adjuster 132 may be set to a high temperature of, for example, 300 degrees C. or higher. In such a case, the elastic member 159 also needs to have further heat resistance, and it is conceivable to use metal (metal seal) as the elastic member 159 that can withstand 300 degrees C. or higher.

In such a case, there is the same problem as when the metal is used for the elastic member 160. That is, when the metal is used for the elastic member 159, it is considered that a large fastening force may be required in order to exhibit sufficient sealing performance. Further, it is considered that the elastic member 159 may not be reused. As described above, a portion to which the elastic member 159 is applied is required to have a structure capable of ensuring the sealing property even at 300 degrees C. or higher and capable of simple operation as the O-ring does.

Further, since the heater terminal 156 is made of metal such as molybdenum or tungsten as described above, it may be oxidized when exposed to the atmosphere, and the electric conductivity of the heater terminal 156 may decrease.

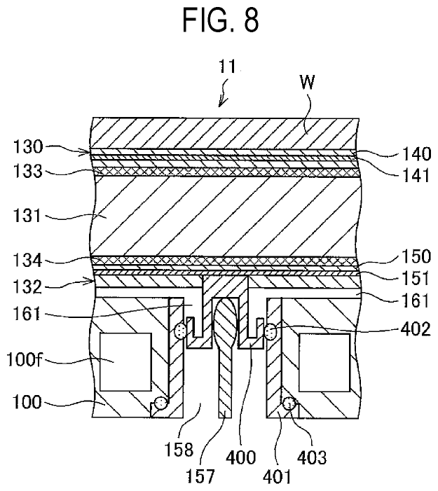

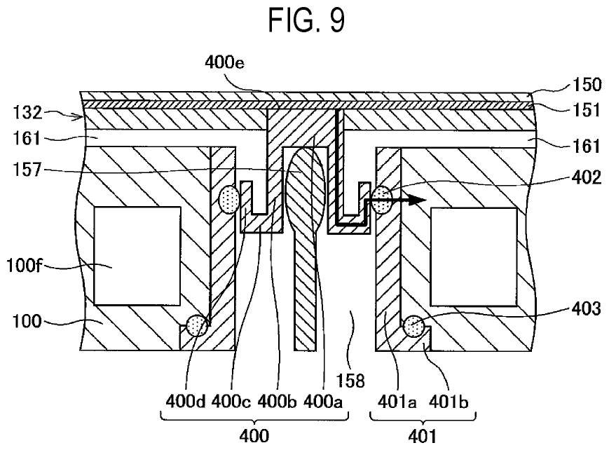

FIG. 8 is an enlarged explanatory view showing a portion of the substrate support assembly 11 according to a first example of another embodiment. FIG. 9 is an enlarged explanatory view showing a seal structure according to the first example of another embodiment. In this embodiment, the temperature (for example, 300 degrees C. or higher) of the substrate temperature adjuster 132 and the temperature (for example, 60 degrees C. or lower) of the base 100 are insulated by a He gas in the heat transfer space 161.

In the first example, instead of the heater terminal 156 and the elastic member 159, a heat insulating terminal 400, an insulating member 401, a second elastic member 402, and a third elastic member 403 are provided in the power feeding space 158. The heat insulating terminal 400 partitions the feeding space 158 and the heat transfer space 161 and is disposed between the heater electrode 151 and a jack pin of the feeding line 157. The insulating member 401 is internally fitted in a through-hole formed in the base 100 and defines the power feeding space 158 for connecting the heater electrode 151 and the power feeding line 157 via the heat insulating terminal 400. The second elastic member 402 is sandwiched between the heat insulating terminal 400 and the insulating member 401. That is, between the heat insulating terminal 400 and the insulating member 401, the heat transfer space 161 side from the second elastic member 402 is filled with a He gas. The third elastic member 403 is disposed between the insulating member 401 and the base 100. That is, between the insulating member 401 and the base 100, the heat transfer space 161 side from the third elastic member 403 is filled with a He gas.

The heat insulating terminal 400 is made of a conductor. Further, it is desirable that the heat insulating terminal 400 has a low thermal conductivity. For example, a metal having a low thermal conductivity such as titanium may be used for the heat insulating terminal 400. Alternatively, the heat insulating terminal 400 may employ a shape having low heat transfer properties, for example, a stainless flexible tube or the like.

The heat insulating terminal 400 has an upper plate portion 400a, an inner cylindrical portion 400b, a lower annular portion 400c, and an outer cylindrical portion 400d. The upper plate portion 400a has substantially a disc shape and provides an upper surface 400e at the upper end thereof. The upper surface 400e is directly connected to the heater electrode 151 and is fixed to the heater electrode 151. The inner cylindrical portion 400b has substantially a cylindrical shape and extends continuously and vertically downward from the outermost side of the lower surface of the upper plate portion 400a. The lower annular portion 400c has substantially an annular plate shape and extends continuously and radially outward from the lower end of the inner cylindrical portion 400b. The outer cylindrical portion 400d has substantially a cylindrical shape and extends continuously and vertically upward from the outermost side of the upper surface of the lower annular portion 400c.

In such a heat insulating terminal 400, by providing the inner cylindrical portion 400b, the lower annular portion 400c, and the outer cylindrical portion 400d, a heat transfer distance from the substrate temperature adjuster 132 to the second elastic member 402 can be lengthened, as will be described later, so that the temperature of the second elastic member 402 can be lowered. Moreover, due to the shape of the heat insulating terminal 400, sufficient heat insulating property can be exhibited even in a reduced space. The shape of the heat insulating terminal 400 is not limited to this embodiment. It suffices, if the heat insulating terminal 400 has a required function, that is, the heat insulating property.

The insulating member 401 is made of an insulating body such as resin or ceramics. The insulating member 401 has a cylindrical portion 401a and a lower flange portion 401b. The cylindrical portion 401a has substantially a cylindrical shape and is provided along the inner side surface of the base 100. The lower flange portion 401b has substantially an annular plate shape and extends continuously and radially outward from the lower end of the cylindrical portion 401a. The cylindrical portion 401a of the insulating member 401 is fitted into the inner side surface of the base 100, and the lower flange portion 401b is engaged with and fixed to the lower surface of the base 100. The insulating member 401 may be integrally formed, or may be divided in the vertical direction.

The second elastic member 402 is in contact with the outer side surface of the outer cylindrical portion 400d of the heat insulating terminal 400 and the inner side surface of the insulating member 401. The second elastic member 402 is, for example, an O-ring and seals the heat transfer space 161. The second elastic member 402 may be buried in the insulating member 401, or may be buried in the heat insulating terminal 400.

The third elastic member 403 is in contact with the upper surface of the lower flange portion 401b of the insulating member 401 and the lower surface of the base 100. The third elastic member 403 is, for example, an O-ring and seals between the insulating member 401 and the base 100. The third elastic member 403 may be buried in the base 100, or may be buried in the insulating member 401.

In such a seal structure, heat is transferred as indicated by an arrow in FIG. 9, and the heat from the substrate temperature adjuster 132 is transferred to the second elastic member 402 via the heat insulating terminal 400. Here, as described above, the thermal conductivity of the heat insulating terminal 400 is low. In addition, since the heat insulating terminal 400 has a shape including the upper plate portion 400a, the inner cylindrical portion 400b, the lower annular portion 400c, and the outer cylindrical portion 400d, the heat transfer distance from the substrate temperature adjuster 132 to the second elastic member 402 can be lengthened. Then, the temperature of the second elastic member 402 can be sufficiently lowered. For example, even when the temperature of the substrate temperature adjuster 132 is 300 degrees C. or higher, for example, 350 degrees C., the temperature can be lowered to a temperature at which the second elastic member 402 is not damaged, for example, 200 degrees C. or lower. As a result, it is possible to stably exhibit the sealing property by the second elastic member 402.

Further, since the O-ring can be used for the second elastic member 402, in comparison with the metal seal, the fastening force can be reduced, so that the number of fastening members 170 can be decreased. Further, the second elastic member 402 can be reused and can be operated more easily than the metal seal.

Further, since the heat insulating terminal 400 is exposed to the heat transfer space 161 and is in contact with a He gas, it is possible to suppress oxidation like the heater terminal 156 shown in FIG. 7 and stabilize the electric resistance. Further, since the He gas has a higher thermal conductivity than the atmosphere, the heat dissipation property is improved, so that the temperature of the second elastic member 402 can be lowered.

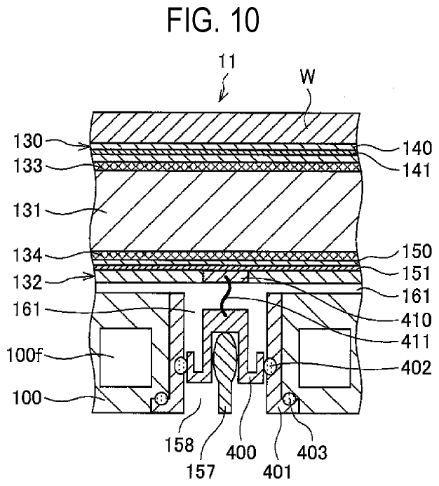

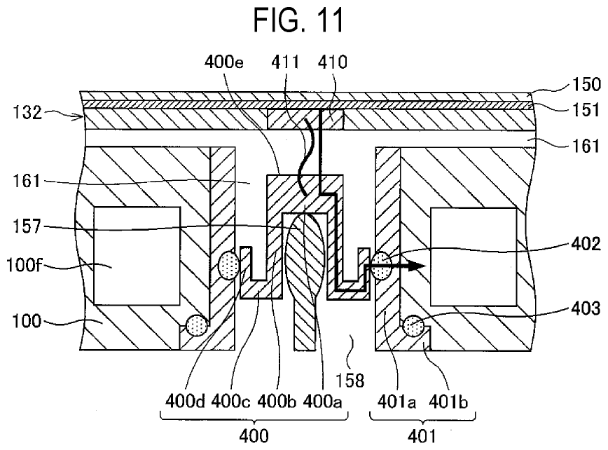

FIG. 10 is an enlarged explanatory view showing a portion of the substrate support assembly 11 according to a second example of another embodiment. FIG. 11 is an enlarged explanatory view showing a seal structure according to the second example of another embodiment.

In the first example, the heat insulating terminal 400 is directly connected to the heater electrode 151, but in the second example, the heat insulating terminal 400 has a connecting member 410 and a flexible member 411 and is connected to the heater electrode 151 via the connecting member 410 and the flexible member 411. The connecting member 410 is directly connected to the heater electrode 151 and is fixed to the heater electrode 151. The connecting member 410 is made of metal. In the second example, the upper plate portion 400a, the inner cylindrical portion 400b, the lower annular portion 400c, and the outer cylindrical portion 400d constitute a main body portion in the present disclosure.

The flexible member 411 connects the connecting member 410 and the heat insulating terminal 400. The flexible member 411 is a deformable member and employs, for example, a flexible conducting wire (twisted wire) or the like. The connecting member 410 is made of metal, for example, copper.

In such a case, the same effects as those of the first example can be enjoyed. Moreover, as indicated by an arrow in FIG. 11, the heat transfer distance from the substrate temperature adjuster 132 to the second elastic member 402 can be further lengthened while increasing a heat dissipation surface by an amount of the flexible member 411, so that the temperature of the second elastic member 402 can be further lowered.

Further, the flexible member 411 can absorb a deviation in the horizontal direction. As described above, there is a difference between the temperature (for example, 300 degrees C. or higher) of the substrate temperature adjuster 132 and the temperature (for example, 60 degrees C. or lower) of the base 100. Therefore, in the case of the first example, since the heat insulating terminal 400 linearly expands in the horizontal direction while being fixed to the heater electrode 151, a horizontal force acts on the heat insulating terminal 400. In the second example, the flexible member 411 can absorb this horizontal force.

The seal structure of the first example and the seal structure of the second example of the present embodiment can be also applied to the substrate support assembly 11 in which both the attraction electrode 141 and the heater electrodes 151 and 152 are provided inside one base layer.

The embodiments disclosed this time should be considered to be exemplary and not restrictive in all respects. The above embodiments may be omitted, replaced, or changed in various forms without departing from the appended claims and the gist thereof.

According to the present disclosure in some embodiments, it is possible to suppress the loss of RF power on the low frequency side with respect to RF power supplied to an RF electrode part in plasma processing.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate support that supports a substrate, comprising:
a substrate attraction part including an attraction electrode for holding the substrate;
an RF electrode part to which RF power is supplied; and
a substrate temperature adjuster including a heater electrode for adjusting a temperature of the substrate,
wherein the substrate attraction part and the substrate temperature adjuster are stacked with the RF electrode part interposed therebetween.

2. The substrate support of claim 1, wherein the substrate attraction part is arranged on an upper surface side of the RF electrode part, and
wherein the substrate temperature adjuster is arranged on a lower surface side of the RF electrode part.

3. The substrate support of claim 1, wherein a thickness of the substrate attraction part is 2 mm or less.

4. The substrate support of claim 1, wherein the substrate attraction part has a first base layer that incorporates the attraction electrode and is made of a dielectric.

5. The substrate support of claim 4, wherein the first base layer is made of metal oxide, and
wherein the substrate attraction part generates a Coulomb force to hold the substrate.

6. The substrate support of claim 4, wherein the first base layer is made of ceramics having a volume resistivity of 1×10¹⁵ Ω·cm or more.

7. The substrate support of claim 4, wherein the first base layer is made of metal nitride, and
wherein the substrate attraction part generates a Johnson-Rahbeck force to hold the substrate.

8. The substrate support of claim 4, wherein the first base layer is made of ceramics having a volume resistivity of 1×10⁻⁸ to 1×10⁻¹¹ Ω·cm.

9. The substrate support of claim 4, wherein the RF electrode part is made of a conductor, and
wherein a difference in coefficient of thermal expansion between the RF electrode part and the first base layer is 1 ppm/degrees C. or less.

10. The substrate support of claim 1, wherein the substrate temperature adjuster has a second base layer that incorporates the heater electrode and is made of a dielectric.

11. The substrate support of claim 10, wherein the RF electrode part is made of a conductor, and
wherein a difference in coefficient of thermal expansion between the RF electrode part and the second base layer is 1 ppm/degrees C. or less.

12. A substrate support assembly including a substrate support of claim 1, comprising:
a base disposed on a lower surface side of the substrate support and has a flow path for a temperature control medium;
a power feeding body connected to the base and transmits the RF power to the RF electrode part via the base;
a first elastic member disposed between the base and the substrate support and separates the substrate support from the base; and
a fastening member sandwiching the first elastic member between the base and the substrate support.

13. The substrate support assembly of claim 12, further comprising:
an edge ring arranged so as to surround the substrate placed on the substrate support;
an edge ring attraction part disposed on an upper surface side of the fastening member and includes a second attraction electrode for holding the edge ring; and
an edge ring temperature adjuster including a second heater electrode for adjusting a temperature of the edge ring,
wherein the edge ring attraction part and the edge ring temperature adjuster are stacked.

14. The substrate support assembly of claim 12, further comprising: a heat insulating member between the first elastic member and the substrate support.

15. The substrate support assembly of claim 14, wherein the heat insulating member has:
an upper annular portion in contact with the substrate support;
a lower annular portion in contact with the first elastic member; and
a cylindrical portion connecting the upper annular portion and the lower annular portion and having a sectional area smaller than that of the upper annular portion.

16. The substrate support assembly of claim 15, wherein the substrate support has a third attraction electrode for holding the heat insulating member.

17. The substrate support assembly of claim 16, wherein the heat insulating member is made of a conductor,
the substrate support assembly further comprising: a contact member disposed between the heat insulating member and the base and electrically conducting the heat insulating member and the base.

18. The substrate support assembly of claim 12, further comprising:
a heat insulating terminal configured to connect the heater electrode and a power feeder line that applies a voltage to the heater electrode;
an insulating member that is internally fitted in a through-hole formed in the base and defines a power feeding space for connecting the heater electrode and a power feeding line via the heat insulating terminal; and
a second elastic member sandwiched between the heat insulating terminal and the insulating member.

19. The substrate support assembly of claim 18, wherein the heat insulating terminal includes:
an inner cylindrical portion connecting the heater electrode and the power feeder line;
an outer cylindrical portion arranged so as to surround the inner cylindrical portion and being in contact with the second elastic member; and
an annular portion connecting the inner cylindrical portion and the outer cylindrical portion.

20. The substrate support assembly of claim 18, wherein the heat insulating terminal includes:
a connecting member connected to the heater electrode;
a main body portion connected to the power feeder line; and
a flexible member connecting the connecting member and the main body portion.

21. A plasma processing apparatus comprising:
a substrate support assembly of claim 12;
a chamber accommodating the substrate support assembly; and
a plasma source generating plasma in the chamber.
